(19) United States
(12) Patent Application Publication
(10) Pub. No.: US 2025/0219324 A1
(43) Pub. Date: Jul. 3, 2025

(54) FLOATING-CONNECTION CHIP TEST CONNECTOR

(71) Applicant: RESEARCH ON ELECTRICAL APPLIANCES OF SHANGHAI ASTRONAUTICS, Shanghai (CN)

(72) Inventors: Hongji Wang, Shanghai (CN); Qifeng Xu, Shanghai (CN); Lei Zhang, Shanghai (CN); Rumin Du, Shanghai (CN)

(21) Appl. No.: 18/852,529

(22) PCT Filed: Dec. 29, 2022
(86) PCT No.: PCT/CN2022/143337

§ 371 Date: Sep. 30, 2024

(30) Foreign Application Priority Data
Mar. 31, 2022 (CN) 202210346446.4

(51) Int. Cl. H01R 13/631; G01R 31/28; H01R 13/42

(52) U.S. Cl. CPC H01R 13/6315; G01R 31/2808; H01R 13/42

(57) ABSTRACT

Provided is floating-connection chip test connector, including metal conductor assembly, plastic base, metal frame, and fixing plate. The metal conductor assembly is connected to plastic base to form connector assembly. The fixing plate connects connector assembly to metal frame. Hole for mounting the metal conductor assembly is arranged in plastic base. Assembly step is arranged on inner wall of the hole. The metal conductor assembly includes body, spring, and elastic snap ring. The spring and elastic snap ring are sleeved on outer side of the body. Diameter of the elastic snap ring in normal state is larger than inner diameter of the assembly step, and diameter in compressed state is smaller than that. Floating force-applying step is arranged on end part of the body. Diameter of the floating force-applying step is larger than diameter of the spring. The spring is located between floating force-applying step and elastic snap ring.

### CROSS-REFERENCE TO RELATED APPLICATION

The present disclosure claims priority to Chinese patent Application No. 202210346446.4, filed with the Chinese Patent Office on Mar. 31, 2022, entitled “FLOATING-CONNECTION CHIP TEST CONNECTOR,” the whole contents of which are incorporated herein by reference.

### TECHNICAL FIELD

The present disclosure relates to the technical field of connecting electrical components, and in particular to a floating-connection chip test connector (a floating-connection connector for chip test).

### BACKGROUND ART

When a cable end panel butts with a PCB end panel, a structure member with a position limitation pin is used for initial positioning first, and then a motor is used to apply force, so that all connectors on two cabinets are properly connected for interconnection.

During the butting process of the cable end panel and the PCB end panel, the butting position between the plug and socket will have a deviation during the butting process of the contact member due to assembly errors between components and assemblies. In order to ensure the reliability of butting, the plug and socket need to have a floating function, and they only need to float at a plane in the butting interface. If a plurality of ports butt at the same time, the butting interface will not be uniform and will also generate deviations. Therefore, the butting ports also need to have the floating function in the butting direction to ensure that all butting ports are well butted. A simple solution is to increase a sliding distance in the butting direction. However, if the butting distance in this direction exceeds 2 mm, simply increasing the sliding distance leads to some problems, such as difficulty in butting, easy failure in butting, and reduced service life for insertion and removal of the connector.

### SUMMARY

In order to overcome deficiencies in related arts, the embodiments of the present disclosure provide a floating-connection connector for chip test.

The embodiments of the present disclosure solve the above technical problems in the following technical manners.

The floating-connection connector for chip test includes a metal conductor assembly, a plastic base, a metal frame, and a fixing plate, wherein the metal conductor assembly is connected to the plastic base to form a connector assembly, and the fixing plate connects the connector assembly to the metal frame; and
a hole for mounting the metal conductor assembly is arranged on the plastic base, and an assembly step is arranged on an inner wall of the hole, wherein the metal conductor assembly includes a body, a spring, and an elastic snap ring, and the spring and elastic snap ring are sleeved on an outer side of the body, wherein an diameter of the elastic snap ring in a normal state is larger than an inner diameter of the assembly step, and a diameter in a compressed state is smaller than the inner diameter of the assembly step; and a floating force-applying step is arranged on an end part of the body, wherein a diameter of the floating force-applying step is larger than a diameter of the spring, and the spring is located between the floating force-applying step and the elastic snap ring.

As an improvement of the above technical solution, an outer wall of the body can be provided with a position limitation step, and an outer diameter of the position limitation step is larger than the diameter of the elastic snap ring in the normal state.

As an improvement of the above technical solutions, a tail step is arranged on one end of a sleeve away from the floating force-applying step, and an outer diameter of the tail step is larger than the inner diameter of the assembly step.

As an improvement of the above technical solutions, a flat washer can be arranged between the spring and the elastic snap ring.

As an improvement of the above technical solutions, the elastic snap ring can be a circular elastic component with a notch, wherein a step with a beveled surface is arranged on an external circumferential surface of the elastic snap ring, which is provided with a characteristic assembly beveled surface, an elastic notch, and a position limitation step, wherein the elastic snap ring is sleeved on the body at the notch with a bottom surface fitting with the position limitation step and a top surface fitting with the flat washer.

As an improvement of the above technical solutions, the flat washer can be a flat component with an opening including an opening and a supporting surface; and the flat washer is arranged on the body at the opening, wherein a bottom supporting surface fits with a top of the elastic snap ring and a top is pressed by the spring to provide the spring with a force applying plane.

As an improvement of the above technical solution, the plastic base can include a positioning flange and a tail boss, wherein the metal conductor assembly is connected to the tail boss, and one side of the positioning flange is connected to the tail boss and the other side is connected to the plastic base, wherein the metal frame is provided with a positioning flange fitting region accommodating the positioning flange, and the metal frame is provided with a fixing plate mounting region connected to a fixing plate, wherein a height difference between the fixing plate mounting region and the positioning flange fitting region is larger than a thickness of the positioning flange, and a fit clearance for the positioning flange is formed between the fixing plate and the positioning flange fitting region; and a floating clearance is arranged between an outer wall of the plastic base and an inner wall of the metal frame, wherein the fit clearance is larger than the floating clearance.

As an improvement of the above technical solutions, the metal frame can be a long-strip metal member in shape of Chinese character “ [symbol] ”, and the metal frame is provided with an upper surface bent on an upper side and a lower surface bent on a lower side respectively, wherein opening holes are arranged in a middle plane for mounting the connector assembly; the fixing plate mounting region is arranged between two opening holes and provided with screw mounting holes thereon; upper and lower sides of the opening holes are provided with regions fitting with the plastic positioning flange; a left position limitation region is arranged on a left side of the opening holes; and a right position limitation region is arranged on a right side of the opening holes.

As an improvement of the above technical solutions, the fixing plate can be fixed with the connector assembly by fastening screws.

As an improvement to the above technical solutions, the metal frame can be provided with four connector assemblies by using four fixing plates and eight fastening screws.

As an improvement to the above technical solutions, the fixing plate can be configured to limit the plastic base; and the fixing plate is provided with a fixing plate mounting hole configured to mount the fastening screws, and is provided with a fixing plate opening hole configured to fit with the tail boss on the plastic base.

### BRIEF DESCRIPTION OF DRAWINGS

FIG. 1 shows a schematic diagram of a three-dimensional structure of a floating-connection connector for chip test in the embodiments of the present disclosure;

FIG. 2 shows a schematic diagram of a main view structure of a floating-connection connector for chip test in the embodiments of the present disclosure;

FIG. 3 shows a schematic diagram of a three-dimensional structure of a metal conductor assembly and a plastic base in the embodiments of the present disclosure;

FIG. 4 shows a schematic diagram of a three-dimensional structure of a plastic base and a metal frame in the embodiments of the present disclosure;

FIG. 5 shows a schematic diagram of a sectional structure of a floating-connection connector for chip test in the embodiments of the present disclosure;

FIG. 6 shows a schematic diagram of a sectional structure of a metal conductor assembly in the embodiments of the present disclosure;

FIG. 7 shows a schematic diagram of a sectional structure of an elastic snap ring in the embodiments of the present disclosure; and

FIG. 8 shows a schematic diagram of a top view structure of an elastic snap ring in the embodiments of the present disclosure.

Reference numbers: metal conductor assembly 41, plastic base 43, metal frame 45, fixing plate 46, assembly step 42 in mounting hole, body 1, spring 4, elastic snap ring 6, floating force-applying step 18, tail step 17, position limitation step 12, flat washer 5, positioning flange 48, tail boss 49, fit clearance 59, and floating clearance 58.

### DETAILED DESCRIPTION OF EMBODIMENTS

In order to make the purpose, technical solutions, and advantages of the embodiments of the present disclosure clearer, the technical solutions in the embodiments of the present disclosure will be described clearly and completely below. It is clear that the embodiments described are only partial embodiments of the present disclosure, and not all of the embodiments. Based on the embodiments in the present disclosure, all other embodiments obtained by a person of ordinary skill in the art without inventive efforts shall fall within the scope of protection of the present disclosure.

It should be noted that when a component is referred to “fix to” the other component, it can be directly arranged on the other component, or a middle component can exist. When a component is considered to be “connected” to another component, it can be directly connected to the other component, or a middle component can exist at the same time.

### EMBODIMENTS

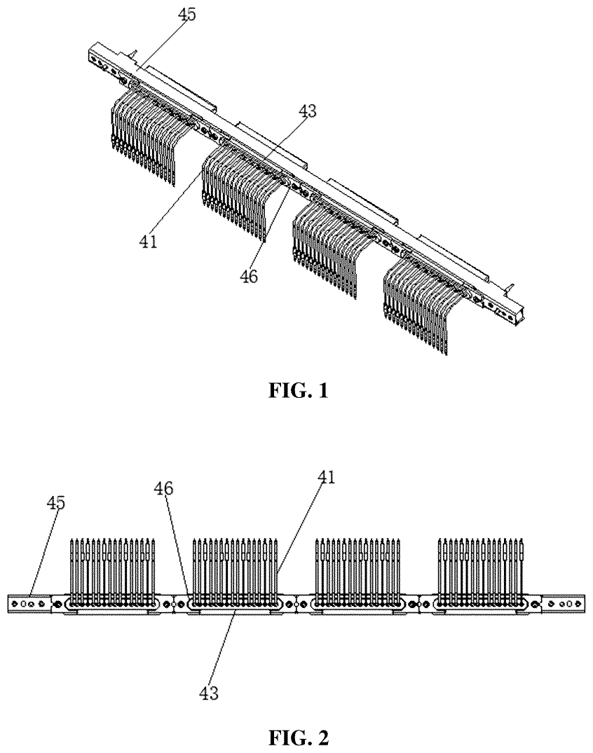

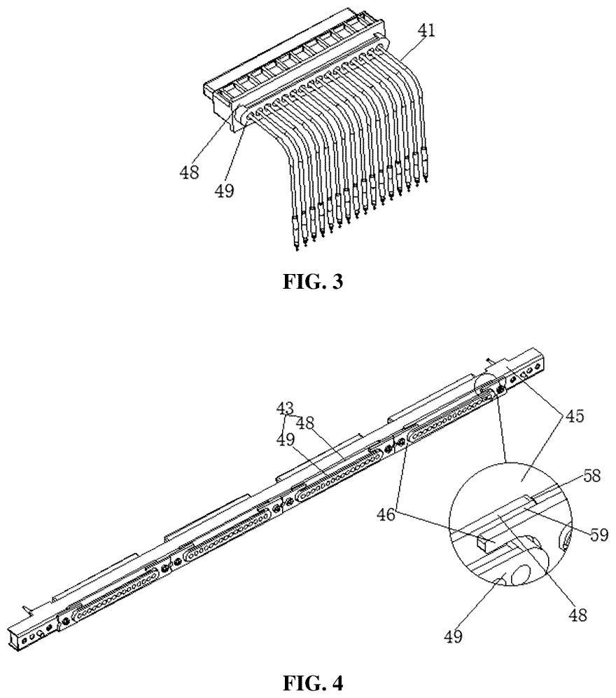

As shown in FIG. 1-FIG. 4, the floating-connection connector for chip test described in the embodiment includes a metal conductor assembly 41, a plastic base 43, a metal frame 45, and a fixing plate 46. The metal conductor assembly 41 is connected to the plastic base 43 to form a connector assembly, and the fixing plate 46 connects the connector assembly to the metal frame 45.

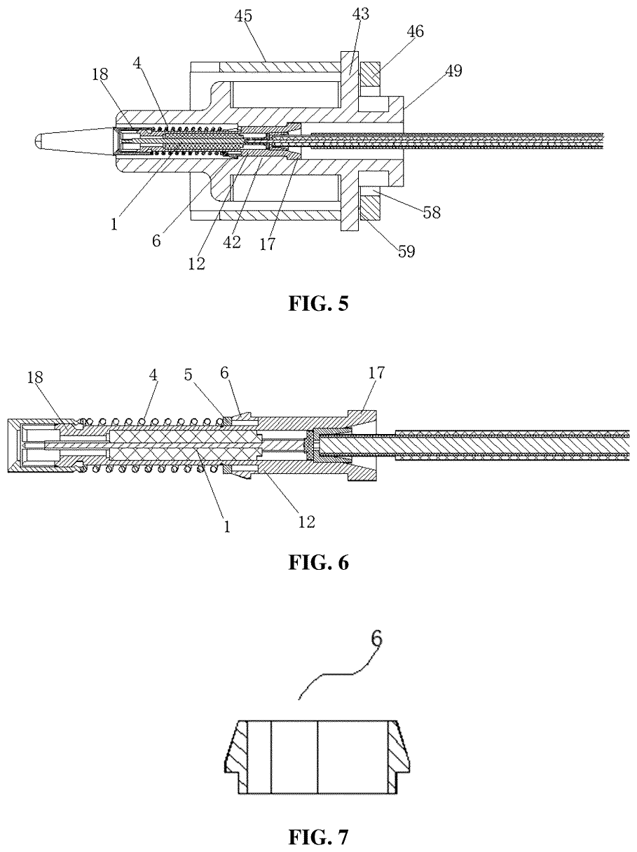

As shown in FIG. 5-FIG. 6, holes for mounting the metal conductor assembly 41 are arranged on the plastic base 43, and an assembly step 42 is arranged on inner wall of the hole. The metal conductor assembly 41 includes a body 1, a spring 4, and an elastic snap ring 6, and the spring 4 and elastic snap ring 6 are sleeved on an outer side of the body 1, wherein a diameter of the elastic snap ring 6 in a normal state is larger than an inner diameter of the assembly step 42, and a diameter in a compressed state is smaller than the inner diameter of the assembly step 42. A floating force-applying step 18 is arranged on an end part of the body 1, wherein a diameter of the floating force-applying step 18 is larger than a diameter of the spring 4, and the spring 4 is located between the floating force-applying step 18 and the elastic snap ring 6.

As shown in FIG. 5-FIG. 6, an outer wall of the body 1 is provided with a position limitation step 12, and an outer diameter of the position limitation step 12 is larger than the diameter of the elastic snap ring 6 in the normal state.

As shown in FIG. 5-FIG. 6, a tail step 17 is arranged on one end of a sleeve away from the floating force-applying step 18, and an outer diameter of the tail step 17 is larger than the inner diameter of the assembly step 42.

As shown in FIG. 5-FIG. 6, a flat washer 5 is arranged between the spring 4 and the elastic snap ring 6.

The floating of the metal conductor assembly 41 in forward and backward directions is realized by the spring 4. One elastic snap ring 6 is arranged on the body 1, and the whole body 1 is mounted through an opening hole in the tail part of the plastic base 43. The elastic snap ring 6 passes through a small hole in the middle part and is snaped at the assembly step 42, so as to prevent the body 1 from moving back. Meanwhile, the body 1 is provided with the tail step 17 to fit with the assembly step 42 of the plastic base 43, so as to prevent the metal conductor assembly 41 from moving forward, so that the metal conductor assembly 41 is limited inside the plastic base 43. When the plug of the connector butts with the socket of the connector, the metal housing of the butting end abuts against the floating force-applying step 18, which leads the body 1 to press the spring 4, so that the whole metal conductor assembly 41 floats backward, wherein the floating distance can be designed according to the requirements of use.

The position limitation step 12 limits a position of the elastic snap ring 6, and at the same time limits a position of the spring 4.

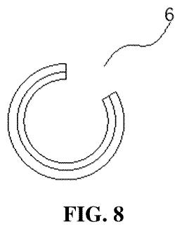

As shown in FIG. 7-FIG. 8, the elastic snap ring 6 is a circular elastic component with a notch, wherein a step with a beveled surface is arranged on an external circumferential surface, which is provided with a characteristic assembly beveled surface, an elastic notch, and a position limitation step. The elastic snap ring 6 is sleeved on the body 1 at the notch with a bottom surface fitting with the position limitation step 12 and a top surface fitting with the flat washer 5.

The flat washer 5 is a flat component with an opening, including the opening and a supporting surface. The flat washer 5 is arranged on the body 1 at the opening, wherein a bottom supporting surface fits with a top of the elastic snap ring 6, and a top is pressed by the spring 4 to provide the spring 4 with a force applying plane.

The spring 4 is a simple component, whose length and spring force are designed according to the requirements of use.

The mounting sequence of whole metal conductor assembly 41 is assembling the elastic snap ring 6 on the body 1 first, wherein the bottom part is supported by the position limitation step 12; mounting the flat washer 5 next, wherein the bottom supporting surface is supported by the top of the elastic snap ring 6; and then mounting the spring 4 from a head part of the body 1.

When the whole metal conductor assembly 41 and the plastic base 43 are assembled, the whole assembly is mounted from the opening hole of the tail part. The assembly beveled surface of the elastic snap ring 6 thereon is pressed by the small hole in the middle. The elastic snap ring 6 passes through the small hole after contracting and deforming, and restores to the original shape at the assembly step 42. The positioning step is snapped at the assembly step 42 of the plastic base 43 to prevent the metal conductor assembly 41 from moving back, and at the same time, the tail step 17 on the body 1 fits with the assembly step 42 on the plastic base 43 to prevent the metal conductor assembly 41 from continuing to move forward.

The metal conductor assembly 41 is assembled in place in this way, and cannot move either forward or backward. When the contact member of the connector at the butting end touches the floating force-applying step 18, the body 1 will press the spring 4, so that the whole metal conductor assembly 41 floats backward, wherein only components that do not move are the elastic snap ring 6 and the flat washer 5. Since the two components are pressed by the spring 4, they will not move forward along the body 1, so that the metal conductor assembly 41 can float in the front and back directions.

As shown in FIG. 1-FIG. 4, the plastic base 43 includes a positioning flange 48 and a tail boss 49, wherein the metal conductor assembly 41 is connected to the tail boss 49, and one side of the positioning flange 48 is connected to the tail boss 49 and the other side is connected to the plastic base 43, wherein the metal frame 45 is provided with a positioning flange fitting region accommodating the positioning flange 48, and the metal frame 45 is provided with a fixing plate mounting region connected to the fixing plate 46, wherein a height difference between the fixing plate mounting region and the positioning flange fitting region is larger than a thickness of the positioning flange 48, and a fit clearance 59 for the positioning flange 48 is formed between the fixing plate 46 and the positioning flange fitting region; and a floating clearance 58 is arranged between an outer wall of the plastic base 43 and an inner wall of the metal frame 45, wherein the fit clearance 59 is larger than the floating clearance 58.

The metal conductor assembly 41 and the plastic base 43 are assembled together to form a plug connector assembly. The metal frame 45 is a long-strip metal member in shape of Chinese character “ [symbol] ”, which forms the main part of the whole structure member. The fixing plate 46 is used to mount the connector assembly, and they are fixed by fastening screws. The whole metal frame 45 is provided with four connector assemblies by using four fixing plates 46 and eight fastening screws, so as to ensure that each connector assembly can float individually.

The metal conductor assembly 41 is connected to the plastic base 43 to form the connector assembly. The mounting and floating of plastic base are characterized by the positioning flange 48, the tail boss 49, the upper surface, the lower surface, the left side surface, and the right side surface.

The metal frame 45 is a long-strip metal member in shape of Chinese character “E”, wherein the metal frame is provided with an upper surface bent on an upper side and a lower surface bent on a lower side respectively; opening holes are arranged in a middle plane for mounting the connector assembly; the fixing plate mounting region is arranged between two opening holes and provided with screw mounting holes thereon; upper and lower sides of the opening holes are provided with regions fitting with the plastic positioning flange; a left position limitation region is arranged on a left side of the opening holes; and a right position limitation region is arranged on a right side of the opening holes.

The fixing plate 46 is configured to limit the position of the plastic base 43; and the fixing plate 46 is provided with the fixing plate mounting holes for mounting the screws, and is provided with the fixing plate opening holes for fitting with the tail boss 49 on the plastic base 43.

After the connector assembly is mounted into the mounting holes of the metal frame, the fixing plate 46 is mounted from the tail part of the plastic base 43, and the connector assembly is assembled to the metal frame 45 by screws. The positioning flange 48 fits with the fitting region for the positioning flange 48 on the metal frame 45; the positioning flange 48 will not pass through the mounting holes; the height difference between the positioning flange fitting region and the fixing plate mounting region is larger than the thickness of the positioning flange of the plastic base; and the fit clearance 59 for the positioning flange 48 is formed between the fixing plate 46 and the positioning flange fitting region, so that the positioning flange 48 can move freely in an enclosed region between the mounting holes and the fixing plate 46. The floating clearance 58 is formed between the outer wall of the plastic base 43 and the inner wall of the metal frame 45, so that the connector assembly can float in any direction within the mounting holes.

Therefore, a plurality of connectors can float at a plurality of port butting interfaces in three-dimensional directions.

It is to be noted that in the text, the relationship terms, such as first and second, are used merely to distinguish one entity or operation from another, and do not necessarily require or imply the existence of any this actual relationship or order between those entities or operations. Furthermore, the terms “include”, “comprise” or any other variations thereof are intended to cover a non-exclusive inclusion, so that a process, method, object, or device including a series of elements includes not only those elements, but also other elements that are not explicitly listed, or the components that are inherent to this process, method, object, or device. Without further limitation, the component defined by a phrase “including a . . . ” does not exclude that the other same elements also exist in the process, method, object, or device including the component.

The above embodiments are only used to illustrate the technical solutions of the present disclosure, and not to restrict it. Although the present disclosure is described in detail with reference to the foregoing embodiments, it should be understood by persons of ordinary skill in the art that they can still modify the technical solutions described in the foregoing embodiments or make equivalent substitutions for some or all of the technical features. Those amendments or substitutions do not make the essence of corresponding technical solution depart from the sprit and scope of the technical solutions of embodiments of the present disclosure.

### INDUSTRIAL APPLICABILITY

The present disclosure provides a floating-connection connector for chip test, including a metal conductor assembly, a plastic base, a metal frame, and a fixing plate, wherein the metal conductor assembly is connected to the plastic base to form a connector assembly, and the fixing plate connects the connector assembly to the metal frame; and a hole for mounting the metal conductor assembly is arranged in the plastic base, and an assembly step is arranged on an inner wall of the hole, wherein the metal conductor assembly includes a body, a spring, and an elastic snap ring, and the spring and elastic snap ring are sleeved on an outer side of the body, wherein an diameter of the elastic snap ring in a normal state is larger than an inner diameter of the assembly step, and the diameter in a compressed state is smaller than the inner diameter of the assembly step; and a floating force-applying step is arranged on an end part of the body, wherein a diameter of the floating force-applying step is larger than a diameter of the spring, and the spring is located between the floating force-applying step and the elastic snap ring. The connector assembly can float in any direction within the mounting holes, and the floating distance can be designed according to the requirements of use, which ensures the good butting of all butting ports, thus ensuring the reliability of butting.

Furthermore, it will be appreciated that the floating-connection connector for chip test of the present disclosure is reproducible, and can be used in a variety of industrial applications. For example, the floating-connection connector for chip test of the present disclosure can be used in the technical field of connecting electrical components.

1. A floating-connection connector for chip test, comprising a metal conductor assembly, a plastic base, a metal frame, and a fixing plate, wherein the metal conductor assembly is connected to the plastic base to form a connector assembly, and the fixing plate connects the connector assembly to the metal frame; and
a hole for mounting the metal conductor assembly is arranged on the plastic base, and an assembly step is arranged on an inner wall of the hole, wherein the metal conductor assembly comprises a body, a spring, and an elastic snap ring, and the spring and the elastic snap ring are sleeved on an outer side of the body, wherein a diameter of the elastic snap ring in a normal state is larger than an inner diameter of the assembly step, and a diameter in a compressed state is smaller than the inner diameter of the assembly step; and a floating force-applying step is arranged on an end part of the body, wherein a diameter of the floating force-applying step is larger than a diameter of the spring, and the spring is located between the floating force-applying step and the elastic snap ring.

2. The floating-connection connector for chip test according to claim 1, wherein an outer wall of the body is provided with a position limitation step, and an outer diameter of the position limitation step is larger than the diameter of the elastic snap ring in the normal state.

3. The floating-connection connector for chip test according to claim 1, wherein a tail step is arranged on one end of a sleeve away from the floating force-applying step, and an outer diameter of the tail step is larger than the inner diameter of the assembly step.

4. The floating-connection connector for chip test according to claim 1, wherein a flat washer is arranged between the spring and the elastic snap ring.

5. The floating-connection connector for chip test according to claim 4, wherein the elastic snap ring is a circular elastic component with a notch; a step with a beveled surface is arranged on an external circumferential surface of the elastic snap ring; and the elastic snap ring is provided with a characteristic assembly beveled surface, an elastic notch, and a position limitation step, wherein the elastic snap ring is sleeved on the body at the notch with a bottom surface fitting with the position limitation step and a top surface fitting with the flat washer.

6. The floating-connection connector for chip test according to claim 4, wherein the flat washer is a flat component with an opening, comprising the opening and a supporting surface, wherein the flat washer is arranged on the body at the opening; a bottom supporting surface of the flat washer fits with a top of the elastic snap ring; and a top of the flat washer is pressed by the spring to provide the spring with a force applying plane.

7. The floating-connection connector for chip test according to claim 1, wherein the plastic base comprises a positioning flange and a tail boss, wherein the metal conductor assembly is connected to the tail boss, and one side of the positioning flange is connected to the tail boss and the other side is connected to the plastic base, wherein the metal frame is provided with a positioning flange fitting region accommodating the positioning flange, and the metal frame is provided with a fixing plate mounting region connected to the fixing plate, wherein a height difference between the fixing plate mounting region and the positioning flange fitting region is larger than a thickness of the positioning flange, and a fit clearance for the positioning flange is formed between the fixing plate and the positioning flange fitting region; and a floating clearance is arranged between an outer wall of the plastic base and an inner wall of the metal frame, wherein the fit clearance is larger than the floating clearance.

8. The floating-connection connector for chip test according to claim 7, wherein the metal frame is a long-strip metal member in shape of Chinese character “ [symbol] ”, and the metal frame is provided with an upper surface bent on an upper side and a lower surface bent on a lower side respectively, wherein opening holes are arranged in a middle plane for mounting the connector assembly; the fixing plate mounting region is arranged between two opening holes and provided with screw mounting holes thereon; upper and lower sides of the opening holes are provided with regions fitting with a plastic positioning flange; a left position limitation region is arranged on a left side of the opening holes; and a right position limitation region is arranged on a right side of the opening holes.

9. The floating-connection connector for chip test according to claim 1, wherein the fixing plate is fixed with the connector assembly by fastening screws.

10. The floating-connection connector for chip test according to claim 9, wherein the metal frame is provided with four connector assemblies by using four fixing plates and eight fastening screws.

11. The floating-connection connector for chip test according to claim 9, wherein the fixing plate is configured to limit the plastic base; and the fixing plate is provided with a fixing plate mounting hole configured to mount the fastening screws, and is provided with a fixing plate opening hole configured to fit with the tail boss on the plastic base.

12. The floating-connection connector for chip test according to claim 2, wherein a tail step is arranged on one end of a sleeve away from the floating force-applying step, and an outer diameter of the tail step is larger than the inner diameter of the assembly step.

13. The floating-connection connector for chip test according to claim 2, wherein a flat washer is arranged between the spring and the elastic snap ring.

14. The floating-connection connector for chip test according to claim 3, wherein a flat washer is arranged between the spring and the elastic snap ring.

15. The floating-connection connector for chip test according to claim 5, wherein the flat washer is a flat component with an opening, comprising the opening and a supporting surface, wherein the flat washer is arranged on the body at the opening; a bottom supporting surface of the flat washer fits with a top of the elastic snap ring; and a top of the flat washer is pressed by the spring to provide the spring with a force applying plane.

16. The floating-connection connector for chip test according to claim 2, wherein the plastic base comprises a positioning flange and a tail boss, wherein the metal conductor assembly is connected to the tail boss, and one side of the positioning flange is connected to the tail boss and the other side is connected to the plastic base, wherein the metal frame is provided with a positioning flange fitting region accommodating the positioning flange, and the metal frame is provided with a fixing plate mounting region connected to the fixing plate, wherein a height difference between the fixing plate mounting region and the positioning flange fitting region is larger than a thickness of the positioning flange, and a fit clearance for the positioning flange is formed between the fixing plate and the positioning flange fitting region; and a floating clearance is arranged between an outer wall of the plastic base and an inner wall of the metal frame, wherein the fit clearance is larger than the floating clearance.

17. The floating-connection connector for chip test according to claim 3, wherein the plastic base comprises a positioning flange and a tail boss, wherein the metal conductor assembly is connected to the tail boss, and one side of the positioning flange is connected to the tail boss and the other side is connected to the plastic base, wherein the metal frame is provided with a positioning flange fitting region accommodating the positioning flange, and the metal frame is provided with a fixing plate mounting region connected to the fixing plate, wherein a height difference between the fixing plate mounting region and the positioning flange fitting region is larger than a thickness of the positioning flange, and a fit clearance for the positioning flange is formed between the fixing plate and the positioning flange fitting region; and a floating clearance is arranged between an outer wall of the plastic base and an inner wall of the metal frame, wherein the fit clearance is larger than the floating clearance.

18. The floating-connection connector for chip test according to claim 2, wherein the fixing plate is fixed with the connector assembly by fastening screws.

19. The floating-connection connector for chip test according to claim 3, wherein the fixing plate is fixed with the connector assembly by fastening screws.

20. The floating-connection connector for chip test according to claim 10, wherein the fixing plate is configured to limit the plastic base; and the fixing plate is provided with a fixing plate mounting hole configured to mount the fastening screws, and is provided with a fixing plate opening hole configured to fit with the tail boss on the plastic base.
